(19) United States
(12) Patent Application Publication
(10) Pub. No.: US 2008/0296663 A1
(43) Pub. Date: Dec. 4, 2008

(54) SEMICONDUCTOR DEVICE AND METHOD OF MANUFACTURING THE SAME

(76) Inventors: Wakako Takeuchi, Yokohama-Shi (JP); Hiroshi Akahori, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/113,245

(22) Filed: May 1, 2008

(30) Foreign Application Priority Data
May 29, 2007 (JP) 2007-142170

(51) Int. Cl. H01L 29/792; H01L 21/28

(52) U.S. Cl. 257/326; 438/591; 257/E29.309; 257/E21.18

(57) ABSTRACT

A semiconductor device according to an embodiment of the present invention includes a first gate insulator, a first gate electrode, a second gate insulator, and a second gate electrode. Regarding the thickness of the second gate insulator, the thickness of the insulator, on a first edge of the first gate electrode in the word-line direction, and the thickness of the insulator, on a second edge of the first gate electrode in the word-line direction, are larger than, the thickness of the insulator, on the upper surface of the first gate electrode, the thickness of the insulator, on the first side of the first gate electrode in the word-line direction, and the thickness of the insulator, on the second side of the first gate electrode in the word-line direction.

### CROSS REFERENCE TO RELATED APPLICATION

This application is based upon and claims the benefit of priority from the prior Japanese Patent Application No. 2007-142170, filed on May 29, 2007, the entire contents of which are incorporated herein by reference.

### BACKGROUND OF THE INVENTION

1. Field of the Invention

The present invention relates to a semiconductor device and a method of manufacturing the same.

2. Background Art

A flash memory is one of nonvolatile semiconductor memories widely used presently. Various electronic devices include flash memories as their memories. Flash memories are also widely used in storage media such as memory cards.

In general, a memory cell of a flash memory includes a first gate insulator, a first gate electrode (a floating gate), a second gate insulator, and a second gate electrode (a control gate).

In the flash memory, the second gate insulator is often formed on an upper surface and sides of the first gate electrode, and the second gate electrode is often formed on an upper surface and sides of the second gate insulator. Such a gate structure has an advantage that the capacitance between the first gate electrode and the second gate electrode is large. On the other hand, such a gate structure has a disadvantage that a voltage applied to edge portions of the second gate insulator (i.e., boundary portions between an upper surface portion and side portions of the second gate insulator) is large. Such a voltage increases a leak current between the first gate electrode and the second gate electrode in the edge portions of the second gate insulator.

JP-A H11-220043 (KOKAI) discloses a method of manufacturing a semiconductor memory including a floating gate. In the manufacturing method, an island-like floating gate is formed, and an oxidation process to oxidize the surface of the floating gate is then performed.

### SUMMARY OF THE INVENTION

An embodiment of the present invention is, for example, a semiconductor device including a bit line and a word line, the semiconductor device including a first gate insulator formed on a substrate, a first gate electrode formed on the first gate insulator, a second gate insulator formed on the first gate electrode, the second gate insulator being in contact with an upper surface of the first gate electrode, a first side of the first gate electrode in a word-line direction, and a second side of the first gate electrode in the word-line direction, and regarding the thickness of the second gate insulator, the thickness of the insulator, on a first edge of the first gate electrode in the word-line direction, and the thickness of the insulator, on a second edge of the first gate electrode in the word-line direction being larger than each of the thickness of the insulator, on the upper surface of the first gate electrode, the thickness of the insulator, on the first side of the first gate electrode in the word-line direction, and the thickness of the insulator, on the second side of the first gate electrode in the word-line direction, and a second gate electrode formed on the second gate insulator, the second gate electrode being in contact with an upper surface of the second gate insulator, a first side of the second gate insulator in the word-line direction, and a second side of the second gate insulator in the word-line direction.

Another embodiment of the present invention is, for example, a method of manufacturing a semiconductor device including a bit line and a word line, the method including depositing a first gate insulator on a substrate, depositing a first gate electrode layer on the first gate insulator, forming plural trenches which penetrate the first gate electrode layer and the first gate insulator and extend in a bit-line direction, to form the first gate electrode layer and the first gate insulator having a strip shape and whose first and second sides in a word-line direction are exposed, embedding, in the plural trenches, an insulator in which the first gate insulator and a part or all of the first gate electrode layer are embedded, altering first and second edges of the first gate electrode layer in the word-line direction, into insulators, depositing a second gate insulator that is in contact with an upper surface of the first gate electrode layer, and first and second sides of the first gate electrode layer in the word-line direction, depositing a second gate electrode layer that is in contact with an upper surface of the second gate insulator, and first and second sides of the second gate insulator in the word-line direction, and forming plural trenches which penetrate the second gate electrode layer, the second gate insulator, and the first gate electrode layer and extend in the word-line direction, to form a first gate electrode and a second gate electrode.

Another embodiment of the present invention is, for example, a method of manufacturing a semiconductor device including a bit line and a word line, the method including depositing a first gate insulator on a substrate, depositing a first gate electrode layer on the first gate insulator, depositing a lower layer of a second gate insulator on the first gate electrode layer, forming plural trenches which penetrate the lower layer of the second gate insulator, the first gate electrode layer, and the first gate insulator and extend in a bit-line direction, to form the lower layer of the second gate insulator, the first gate electrode layer, and the first gate insulator having a strip shape and whose first and second sides in a word-line direction are exposed, embedding, in the plural trenches, an insulator in which the first gate insulator and a part or all of the first gate electrode layer are embedded, altering first and second edges of the first gate electrode layer in the word-line direction, into insulators, depositing an upper layer of the second gate insulator that is in contact with an upper surface of the lower layer of the second gate insulator, and first and second sides of the lower layer of the second gate insulator in the word-line direction, depositing a second gate electrode layer that is in contact with an upper surface of the upper layer of the second gate insulator, and first and second sides of the upper layer of the second gate insulator in the word-line direction, and forming plural trenches which penetrate the second gate electrode layer, the second gate insulator, and the first gate electrode layer and extend in the word-line direction, to form a first gate electrode and a second gate electrode.

### BRIEF DESCRIPTION OF THE DRAWINGS

FIGS. 1A and 1B are a plan view and a circuit configuration showing the cell array structure of a semiconductor device according to a first embodiment;

FIG. 2 is a side sectional view of the semiconductor device according to the first embodiment;

FIG. 3 is an enlarged side sectional view of the semiconductor device according to the first embodiment;

FIG. 4 is a projected sectional view of the semiconductor device according to the first embodiment;

FIG. 5 is a side sectional view of the semiconductor device according to the first embodiment;

FIG. 6 is a side sectional view of a semiconductor device according to a first comparative example;

FIG. 7 is a side sectional view of a semiconductor device according to a second comparative example;

FIG. 8 is a graph representing a relation between layer thickness and a leak current in the comparative examples;

FIG. 9 is a graph representing a relation between layer thickness and a leak current in the embodiment;

FIGS. 10A to 10L illustrate a manufacturing process of the semiconductor device according to the first embodiment;

FIG. 11 is a side sectional view of a semiconductor device according to a second embodiment;

FIG. 12 is an enlarged side sectional view of the semiconductor device according to the second embodiment;

FIG. 13 is a projected sectional view of the semiconductor device according to the second embodiment;

FIG. 14 is a side sectional view of the semiconductor device according to the second embodiment; and

FIGS. 15A to 15L illustrate a manufacturing process of the semiconductor device according to the second embodiment.

### DESCRIPTION OF THE EMBODIMENTS

### First Embodiment

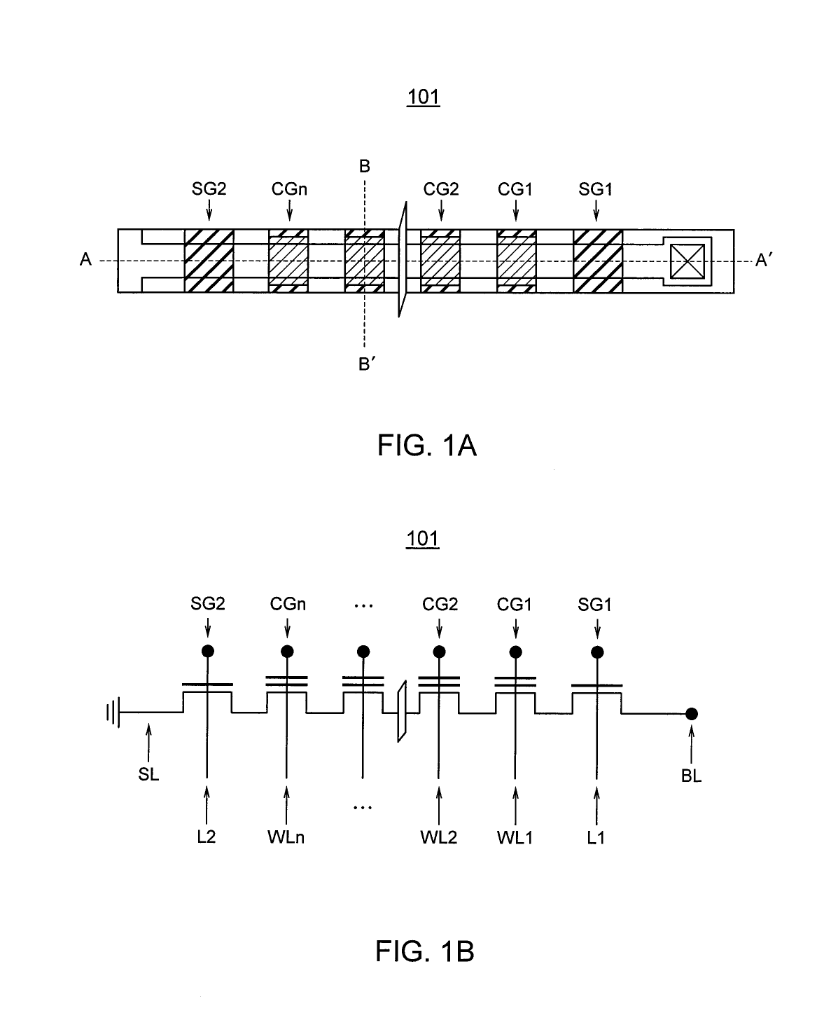

FIGS. 1A and 1B are a plan view and a circuit configuration showing the cell array structure of a semiconductor device 101 according to a first embodiment. In this embodiment, the semiconductor device 101 is a nonvolatile semiconductor storage device, more specifically, a flash memory. The semiconductor device 101 is a NAND flash memory in this embodiment, but may be another type of flash memory such as a MONOS flash memory.

FIGS. 1A and 1B show plural cell transistors CG1 to CGn. These cell transistors are N-channel MOSFETs and connected in series in order of CG1, CG2, . . . , and CGn. The drain of the cell transistor CG1 is connected to a bit line BL via a selection transistor SG1. The source of the cell transistor CGn is connected to a source line SL via a selection transistor SG2.

The cell transistors CG1 to CGn are formed on an identical well substrate. The gates of the cell transistors CG1 to CGn (control gates) are connected to word lines WL1 to WLn, respectively. Each of the word lines WL1 to WLn has a terminal formed on an isolation layer. The gates of the selection transistors SG1 and SG2 (control gates) are connected to selection lines L1 and L2, respectively.

The semiconductor device 101 includes plural bit lines (BL and the like) and plural word lines (WL1 to WLn). These bit lines extend in a line A-A′ direction (a lateral direction) in FIG. 1A. These word lines extend in a line B-B′ direction (a vertical direction) in FIG. 1A. In this way, in FIG. 1A, the line A-A′ direction is a direction parallel to the bit lines (hereinafter referred to as “bit-line direction”), and the line B-B′ direction is a direction parallel to the word lines (hereinafter referred to as “word-line direction”).

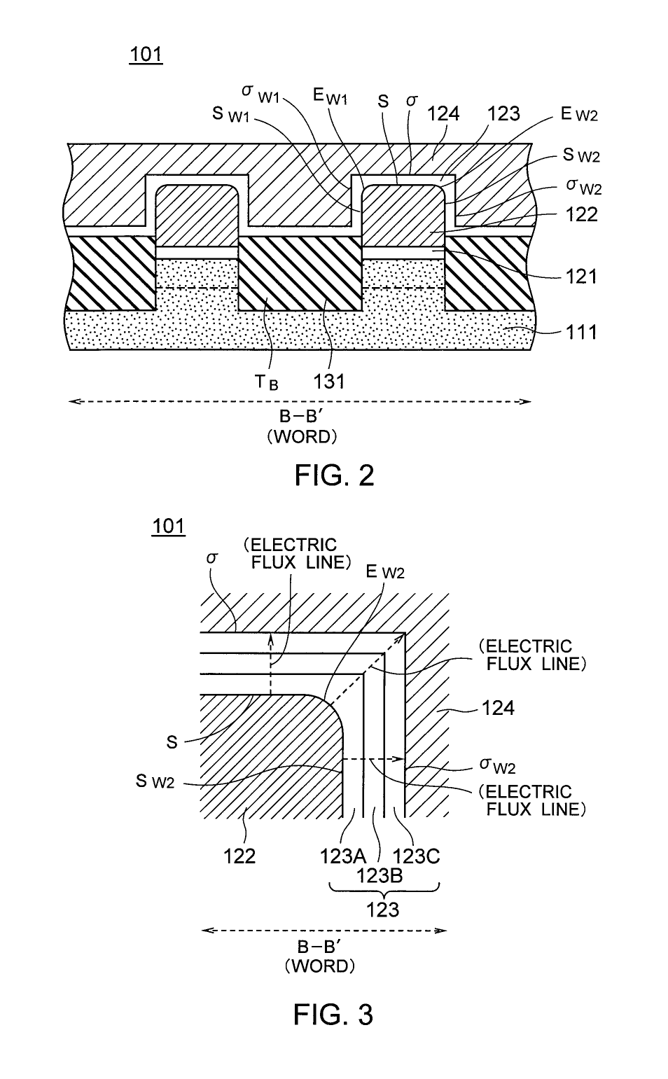

FIG. 2 is a side sectional view of the semiconductor device 101 according to the first embodiment. The semiconductor device 101 shown in FIG. 2 is identical with the semiconductor device 101 shown in FIGS. 1A and 1B. FIG. 2 is a sectional view on the line B-B′ shown in FIG. 1A. As shown in FIG. 2, the semiconductor device 101 includes a substrate 111, a first gate insulator 121, a first gate electrode 122, a second gate insulator 123, a second gate electrode 124, and an embedded insulator 131.

The substrate 111 is a bulk silicon substrate in this embodiment. The substrate 111 may be a bulk semiconductor substrate or an SOI (Semiconductor On Insulator) substrate.

The first gate insulator 121 is formed on the substrate 111, and is in contact with an upper surface of the substrate 111. The first gate insulator 121 is called tunnel insulator. In this embodiment, the first gate insulator 121 is a silicon oxide layer.

The first gate electrode 122 is formed on the first gate insulator 121, and is in contact with an upper surface of the first gate insulator 121. The first gate electrode 122 is called floating gate, and functions as a gate electrode for charge accumulation. In respective memory cells, information is stored and erased according to injection and discharge of charges. In this embodiment, the first gate electrode 122 is a polysilicon layer.

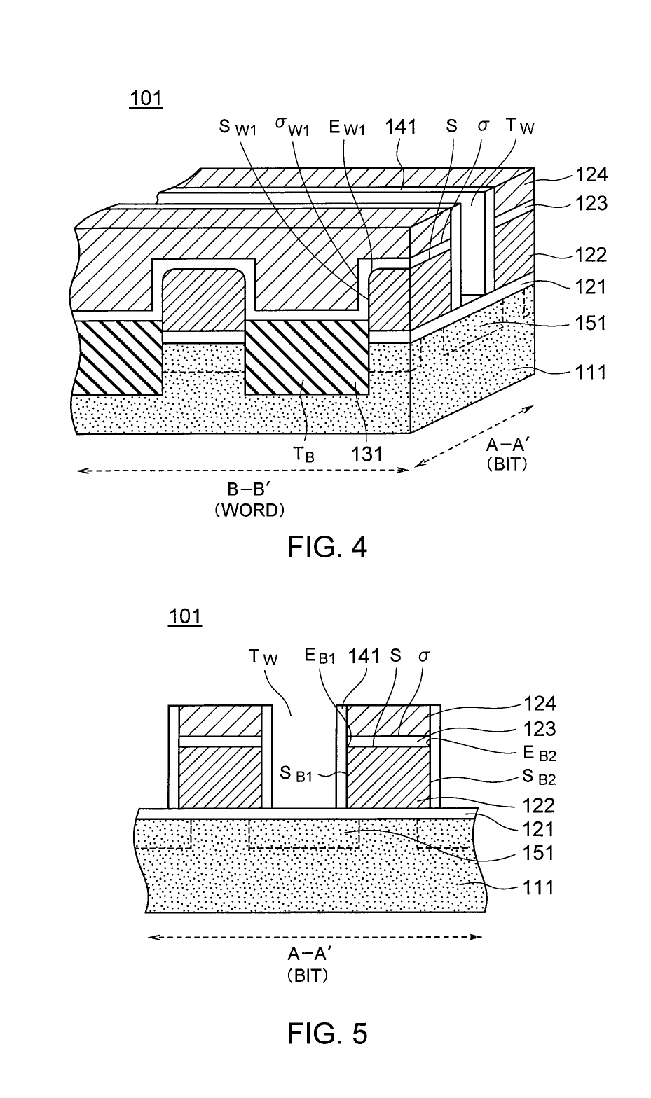

The second gate insulator 123 is formed on the first gate electrode 122, and is in contact with an upper surface of the first gate electrode 122 (S), a first side of the first gate electrode 122 in the word-line direction (S_{W1}), and a second side of the first gate electrode 122 in the word-line direction (S_{W2}). In this embodiment, the second gate insulator 123 is a laminated layer including a silicon oxide layer 123A, a silicon nitride layer 123B, and a silicon oxide layer 123C (see FIG. 3). FIG. 3 is an enlarged view of FIG. 2.

The second gate electrode 124 is formed on the second gate insulator 123, and is in contact with an upper surface of the second gate insulator 123 (σ), a first side of the second gate insulator 123 in the word-line direction (σ_{W1}), and a second side of the second gate insulator 123 in the word-line direction (σ_{W2}). The second gate electrode 124 is called control gate, and functions as a gate electrode for control. In this embodiment, the second gate electrode 124 is a polysilicon layer.

The embedded insulator 131 is formed on the substrate 111, and embedded in a trench T_{B} that extends in the bit-line direction. In this embodiment, the embedded insulator 131 is a silicon oxide layer.

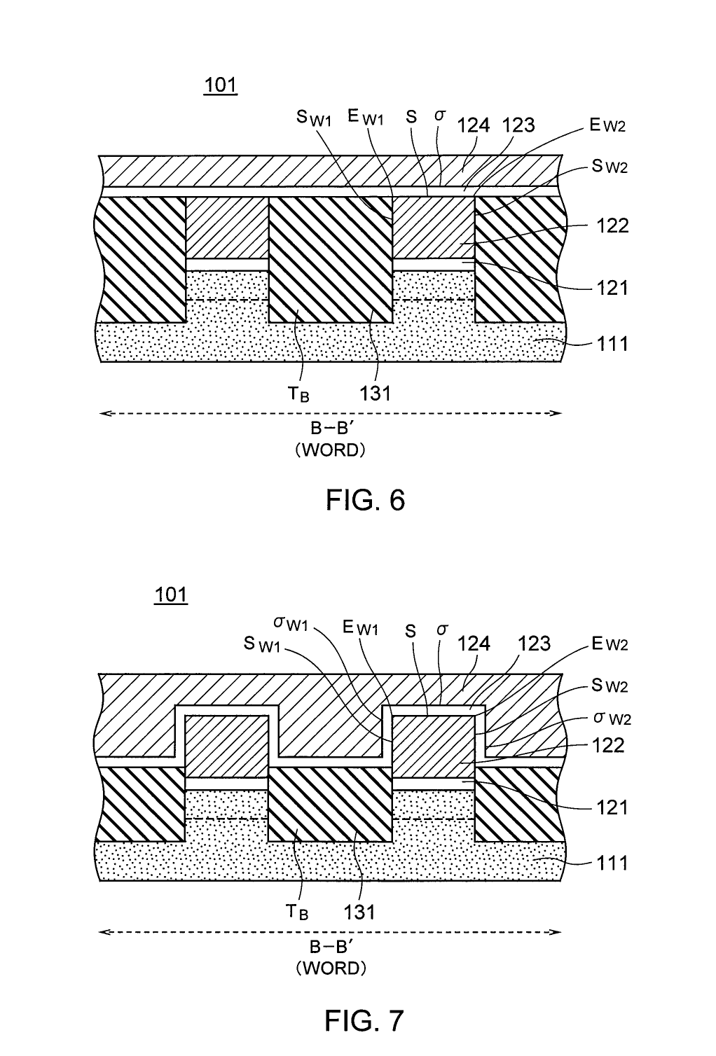

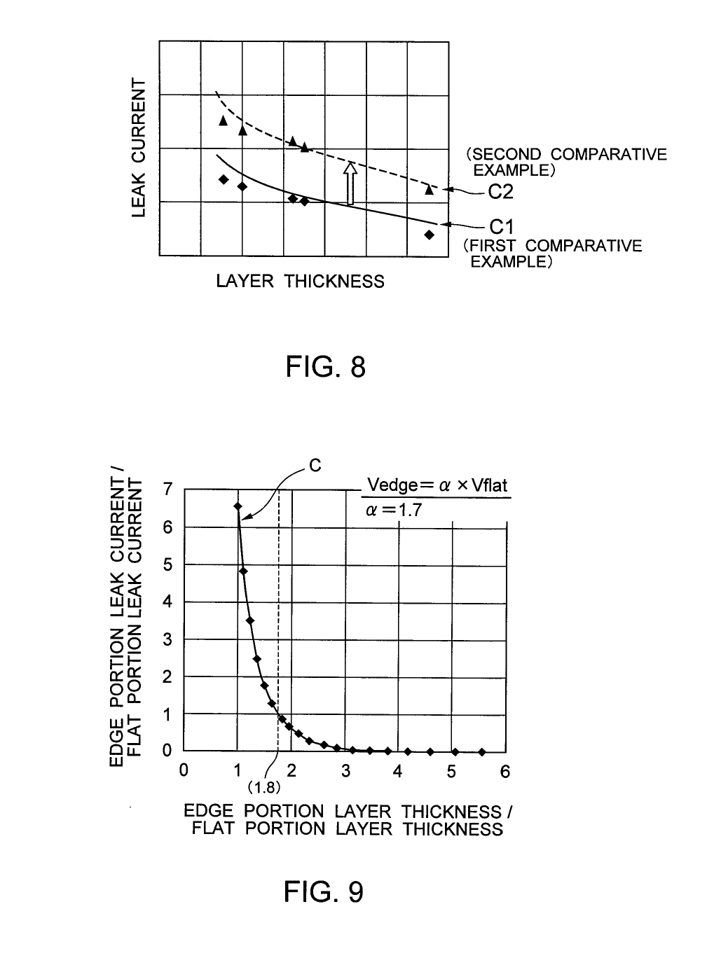

A projected sectional view and a side sectional view of the semiconductor device 101 are shown in FIGS. 4 and 5, respectively. FIG. 4 is a sectional view on the line A-A′ and the line B-B′ shown in FIG. 1A. FIG. 5 is a sectional view on the line A-A′ shown in FIG. 1A. As shown in FIGS. 4 and 5, the semiconductor device 101 further includes sidewall insulators 141, and a source/drain diffusion layer 151. A sidewall insulator 141 is formed on the surface of a sidewall of a trench T_{W} that extends in the word-line direction. In this embodiment, the sidewall insulator 141 is a silicon oxide layer, and is a post-oxidation layer formed by a post-oxidation process. The source/drain diffusion layer 151 is formed in the substrate 111.

The thickness of the second gate insulator 123 is explained below.

As shown in FIG. 2, the second gate insulator 123 is present on the upper surface of the first gate electrode 122 (S), the first side of the first gate electrode 122 in the word-line direction (S_{W1}), the second side of the first gate electrode 122 in the word-line direction (S_{W2}), and an upper surface of the embedded insulator 131. On the other hand, as shown in FIG. 5, the second gate insulator 123 is not present on a first side of the first gate electrode 122 in the bit-line direction (S_{B1}), and a second side of the first gate electrode 122 in the word-line direction (S_{B2}).

In this embodiment, the thickness of the second gate insulator 123 is substantially uniform in most of the second gate insulator 123. The thickness of the insulator 123 on the upper surface S is represented as T. The thickness of the insulator 123 on the first side S_{W1} is represented as T_{W1}. The thickness of the insulator 123 on the second side S_{W2} is represented as T_{W2}. In this embodiment, the thickness T, the thickness T_{W1}, and the thickness T_{W2} are substantially the same. This relation is represented by T=T_{W1}=T_{W2}(=t).

FIG. 2 shows a first edge of the first gate electrode 122 in the word-line direction (E_{W1}), which is a boundary between the upper surface S and the first side S_{W1}. Furthermore, FIG. 2 shows a second edge of the first gate electrode 122 in the word-line direction (E_{W2}), which is a boundary between the upper surface S and the second side S_{W2}.

The thickness of the insulator 123 on the first edge E_{W1} is represented as t_{w1}. The thickness of the insulator 123 on the second edge E_{W2} is represented as t_{W2}. In this embodiment, each of the thickness t_{w1} and the thickness t_{w2} is larger than each of the thickness T, the thickness T_{W1}, and the thickness T_{W2}. This relation is represented by t_{w1}>t and t_{w2}>t.

FIG. 5 shows a first edge of the first gate electrode 122 in the bit-line direction (E_{B1}), which is a boundary between the upper surface S and the first side S_{B1}. Furthermore, FIG. 5 shows a second edge of the first gate electrode 122 in the bit-line direction (E_{B2}), which is a boundary between the upper surface S and the second side S_{B2}.

The thickness of the insulator 123 on the first edge E_{B1} is represented as t_{B1}. The thickness of the insulator 123 on the second edge E_{B2} is represented as t_{B2}. In this embodiment, each of the thickness t_{B1} and the thickness t_{B2} is substantially the same as each of the thickness T, the thickness T_{W1}, and the thickness T_{W2}. This relation is represented by t_{B1}=t and t_{B2}=t.

As described above, in this embodiment, each of the thickness t_{W1} and the thickness t_{W2} is larger than each of the thickness T, the thickness T_{W1}, the thickness t_{W2}, the thickness t_{B1}, and the thickness t_{B2}. This relation is represented by t_{w1}, t_{w2}>T, T_{w1}, T_{w2}, t_{B1}, t_{B2}.

FIG. 3 shows electric flux lines in the second gate insulator 123. FIG. 3 shows an electric flux line on the upper surface S, an electric flux line on the second side S_{W2}, and an electric flux line on the second edge E_{W2}, as examples of the electric flux lines in the second gate insulator 123. The thicknesses of the respective portions of the second gate insulator 123 are defined in directions of these electric flux lines. Therefore, in this embodiment, the thickness T is defined in a vertical direction in FIG. 3. Further, in this embodiment, the thickness T_{W2} is defined in a horizontal direction in FIG. 3. Further, in this embodiment, the thickness t_{W2} is defined in an oblique direction in FIG. 3.

“Thickness” in the above explanation means the capacity thickness of the second gate insulator 123. The capacity thickness d is defined by d=ε₀·ε·S/C. In the above, ε₀ represents a permittivity of vacuum, ε represents a relative permittivity of SiO₂ (silicon dioxide), S represents a capacitor area, and C represents a capacitance. In this embodiment, it is desirable to set each of the capacity thickness t_{W1} and the capacity thickness t_{W2} to be equal to or larger than 1.8 times as large as the capacity thickness T, as described later. This relation is represented by t_{W1}, t_{W2}≧1.8×T.

Semiconductor devices 101 according to first and second comparative examples are explained below.

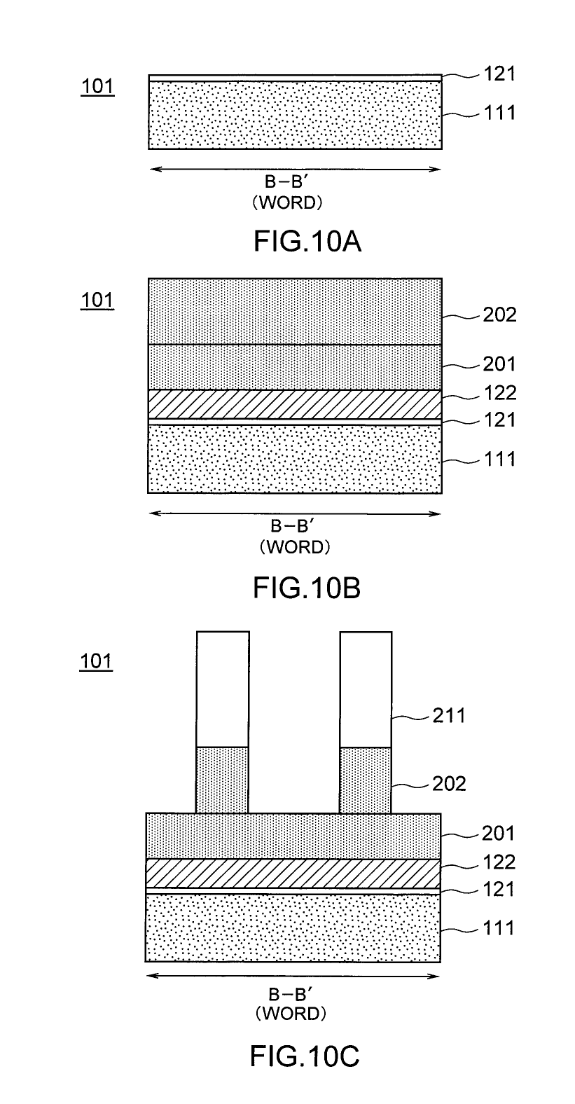

FIG. 6 is a side sectional view (B-B′ sectional view) of the semiconductor device 101 according to the first comparative example. In the first comparative example, the second gate insulator 123 is in contact with the upper surface of the first gate electrode 122 (S), but is not in contact with the first and second sides of the first gate electrode 122 in the word-line direction (S_{W1} and S_{W2}).

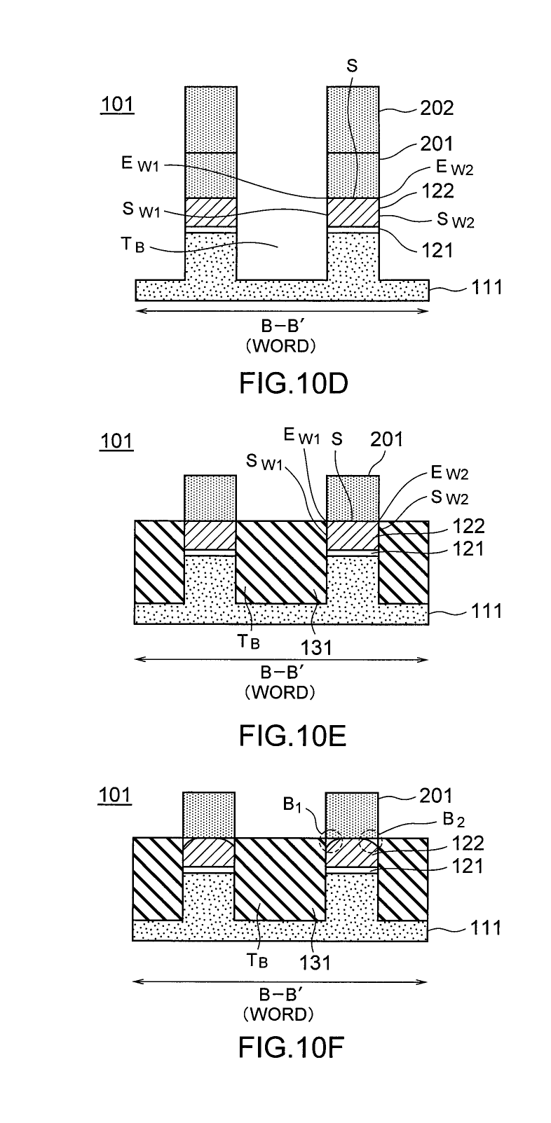

FIG. 7 is a side sectional view (B-B′ sectional view) of the semiconductor device 101 according to the second comparative example. In the second comparative example, as in the first embodiment, the second gate insulator 123 is in contact with the upper surface of the first gate electrode 122 (S), and the first and second sides of the first gate electrode 122 in the word-line direction (S_{W1} and S_{W2}). However, in the second comparative example, the thickness of the second gate insulator 123 is substantially uniform in the all of the second gate insulator 123.

Compared with the first comparative example, the second comparative example has an advantage that the capacitance between the first gate electrode 122 and the second gate electrode 124 is large. On the other hand, compared with the first comparative example, the second comparative example has a disadvantage that a voltage applied to edge portions of the second gate insulator 123 in the word-line direction (i.e., portions of the second gate insulator 123 on the first and second edges E_{W1} and E_{W2}) is large. Such a voltage increases a leak current between the first gate electrode 122 and the second gate electrode 124, in the edge portions of the second gate insulator 122 in the word-line direction.

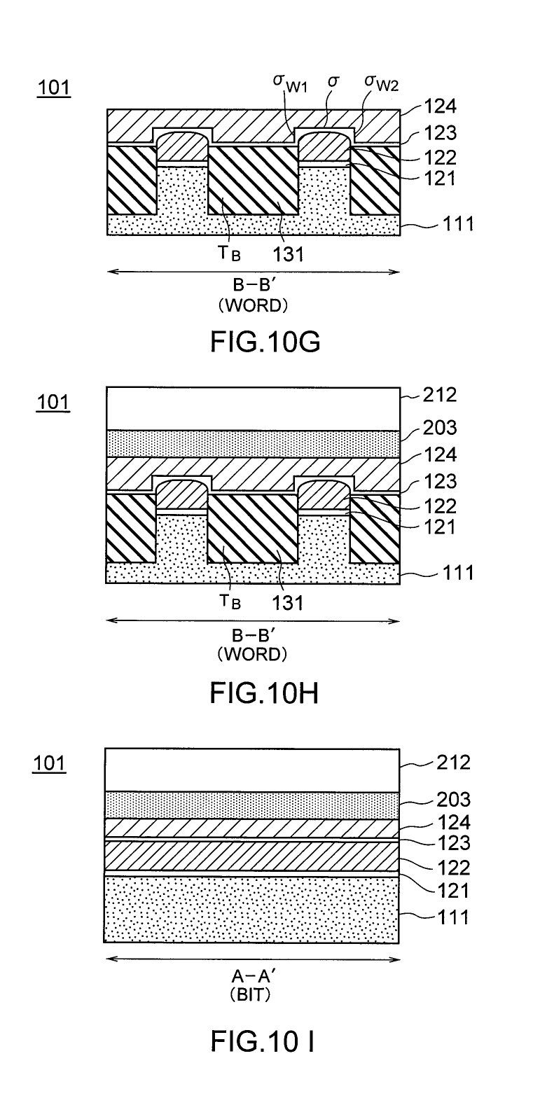

FIG. 8 is a graph representing a relation between layer thickness and a leak current in the first and second comparative examples. A curve C1 represents a result of measurement of a leak current in the first comparative example. A curve C2 represents a result of measurement of a leak current in the second comparative example. Each of them is a leak current between the first gate electrode 122 and the second gate electrode 124, in portions of the second gate insulator 122 on the S, S_{W1}, S_{W2}, E_{W1}, and E_{W2}.

It is understood from the graph in FIG. 8 that the leak current in the second comparative example is larger than the leak current in the first comparative example. According to the measurement results, it was understood that the leak current in the second comparative example was about one digit larger than the leak current in the first comparative example, i.e., about 10 to 100 times as large as the leak current in the first comparative example.

In this embodiment, the advantage of the second comparative example is used while the disadvantage of the second comparative example is reduced. Therefore, the thickness of the second gate insulator 123 of the edge portions in the word-line direction is set larger than the thickness of the second gate insulator 123 of flat portions. This relation is represented by t_{W1}, t_{W2}>T, T_{W1}, t_{W2}, t_{B1}, t_{B2}. Consequently, the leak current between the first gate electrode 122 and the second gate electrode 124, in the edge portions of the second gate insulator 122 in the word-line direction, is reduced.

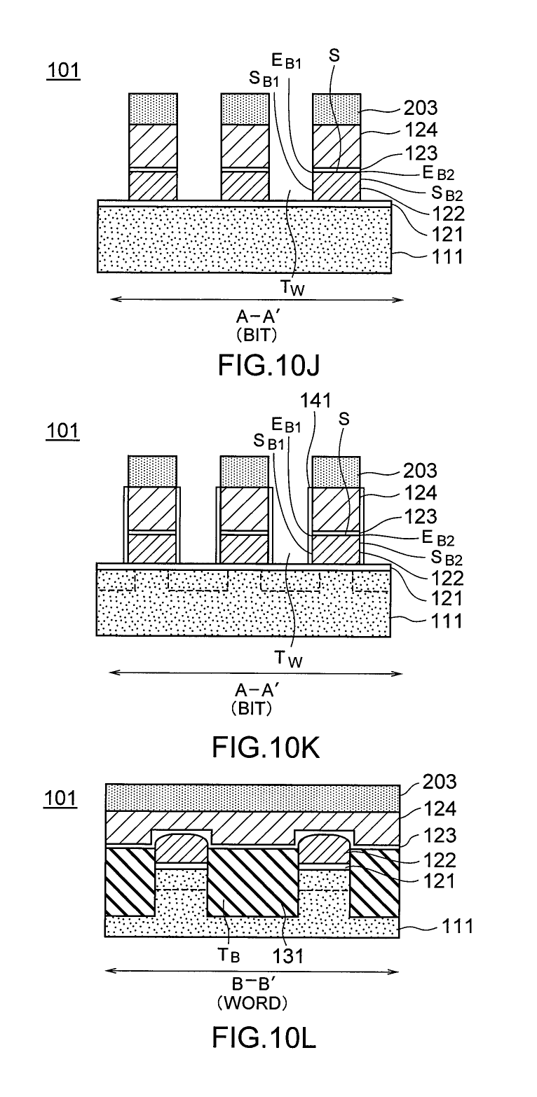

FIG. 9 is a graph representing a relation between layer thickness and a leak current in this embodiment. A curve C represents a result of numerical calculation concerning a leak current in this embodiment. This is a leak current between the first gate electrode 122 and the second gate electrode 124, in portions of the second gate insulator 122 on the S, S_{W1}, S_{W2}, E_{W1}, and E_{W2}. The abscissa in FIG. 9 represents a value obtained by dividing the thickness of the edge portions by the thickness of the flat portions. The ordinate in FIG. 9 represents a value obtained by dividing a leak current in the edge portions by a leak current in the flat portions.

Details of the numerical calculation are explained. The numerical calculation was performed using an expression of an FN (Fowler-Nordheim) current. This expression is represented by J=A·Eₒₓ²·exp(−B/Eₒₓ). In the numerical calculation, the ratio of a voltage applied to the edge portions and a voltage applied to the flat portions was set to 1.7 (V_{edge}/V_{flat}=α=1.7). This value is typical in a semiconductor device having a similar structure to the semiconductor device 101 of this embodiment (e.g., a NAND flash memory in a 55 nm rule).

It is understood from the graph in FIG. 9 that, when the thickness of the edge portions is increased, the leak current in the edge portions is reduced. Therefore, in this embodiment, each of the thickness t_{W1} and the thickness t_{W2} is set larger than the thickness T, the thickness T_{W1}, the thickness T_{W2}, the thickness t_{B1}, and the thickness t_{B2}. Consequently, the leak current in the edge portions is reduced.

It is further understood from the graph in FIG. 9 that, when the ratio of the thickness of the edge portions and the thickness of the flat portions is equal to or larger than 1.8, the ratio of the leak current in the edge portions and the leak current in the flat portions is equal to or lower than 1.0. Therefore, in this embodiment, it is desirable to set each of the capacity thickness t_{W1} and the capacity thickness t_{W2} to be 1.8 time or more as large as the capacity thickness T. Consequently, the leak current in the edge portions is reduced to be equal to or smaller than the leak current in the flat portions.

The thickness T, the thickness T_{W1}, the thickness T_{W2}, the thickness t_{B1}, and the thickness t_{B2} do not have to be the same.

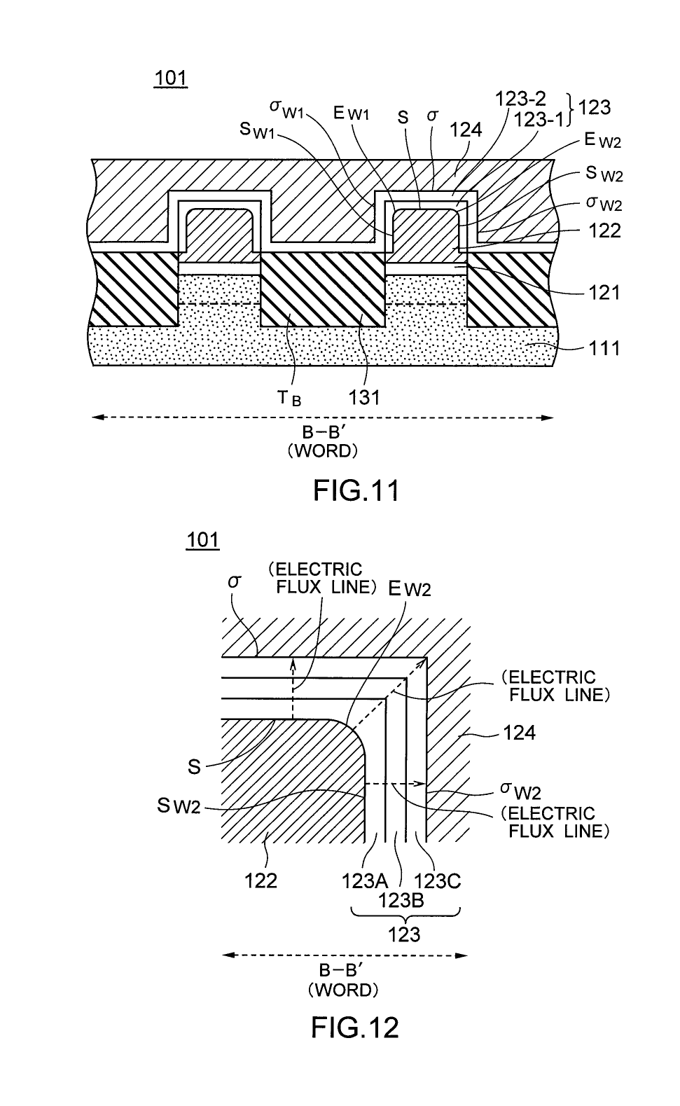

FIGS. 10A to 10L illustrate a manufacturing process of the semiconductor device 101 according to the first embodiment. The semiconductor device 101 is identical with the semiconductor device 101 shown in FIGS. 1A and 1B. FIGS. 10A to 10H are sectional views on the line B-B′ shown in FIG. 1A. FIGS. 10I to 10K are sectional views on the line A-A′ shown in FIG. 1A. FIG. 10L is a sectional view on the line B-B′ shown in FIG. 1A.

First, a first gate insulator 121 as a silicon oxide layer is deposited on a silicon substrate 111 by thermal oxidation (FIG. 10A).

Next, a first gate electrode layer 122 as a polysilicon layer is deposited on the first gate insulator 121 by CVD. Next, a mask material 201 as a silicon nitride layer is deposited on the first gate electrode layer 122 by CVD. Next, a mask material 202 as an oxide layer is deposited on the mask material 201 by CVD (FIG. 10B).

Next, a photoresist 211 is applied on the mask material 202. Next, the mask material 202 is processed by lithography (FIG. 10C).

Next, the photoresist 211 is removed. Next, the mask material 201, the first gate electrode layer 122, the first gate insulator 121, and the substrate 111 are processed (FIG. 10D). In this way, plural trenches T_{B} that penetrate the first gate electrode layer 122 and the first gate insulator 121 and extend in the bit-line direction, are formed. Consequently, the first gate electrode layer 122 and the first gate insulator 121 having a strip shape and whose first and second sides in the word-line direction are exposed, are formed. In FIG. 10D, an upper surface of the first gate electrode layer 122 (S), first and second sides of the first gate electrode layer 122 in the word-line direction (S_{W1} and S_{W2}), and first and second edges of the first gate electrode layer 122 in the word-line direction (E_{W1} and E_{W2}) are shown.

Next, an embedded insulator 131 is deposited in each of the trenches T_{B}. Next, the embedded insulator 131 is polished and planarized by CMP until an upper surface of the mask material 201 is exposed. Consequently, the embedded insulator 131 and the mask material 202 up to the upper surface of the mask material 201 are removed. Next, the height of the upper surface of the embedded insulator 131 is lowered by etching. Consequently, the height of the upper surface of the embedded insulator 131 is lowered to the height of the upper surface S of the first gate electrode layer 122 (FIG. 10E).

In this way, at the stage shown in FIG. 10E, the upper surface S, the first side S_{W1}, and the second side S_{W2} of the first gate electrode layer 122 are covered with insulators. The upper surface S is covered with the mask material 201. The first side S_{W1} and the second side S_{W2} are covered with the embedded insulator 131.

In this embodiment, the first side S_{W1} and the second side S_{W2} are entirely covered with the embedded insulator 131. However, the first side S_{W1} and the second side S_{W2} may be partially covered with the embedded insulator 131. In other words, at the stage shown in FIG. 10E, all of the first gate electrode layer 122 may be embedded in the insulator 131, or a part of the first gate electrode layer 122 may be embedded in the insulator 131.

The height of the upper surface of the embedded insulator 131 is set to a height that makes it possible to insert bird's beaks B₁ and B₂ in the first edge E_{W1} and the second edge E_{W2} of the first gate electrode layer 122, respectively. This condition defines an upper limit of the height of the upper surface of the embedded insulator 131. Details of the bird's beaks B₁ and B₂ are described later.

Further, the height of the upper surface of the embedded insulator 131 is set larger than the height of a lower surface of the first gate electrode layer 122. In other words, the first side S_{W1} and the second side S_{W2} can be partially exposed, but cannot be completely exposed. This is for limiting areas where the bird's beaks B₁ and B₂ are inserted in the first side S_{W1} and the second side S_{W2}, to a part of the first side S_{W1} and the second side S_{W2}. This condition defines a lower limit of the height of the upper surface of the embedded insulator 131.

The explanation of the manufacturing process is resumed.

Next, an oxidation process is applied to a wafer surface to form the bird's beaks B₁ and B₂ in the first edge E_{W1} and the second edge E_{W2} of the first gate electrode layer 122 (FIG. 10F). In other words, the first edge E_{W1} and the second edge E_{W2} of the first gate electrode layer 122 are altered into insulators. In this embodiment, the insulators are oxides, more specifically, silicon oxides. The bird's beaks B₁ and B₂ are formed in a part of the upper surface S, and a part of the first and second sides S_{W1} and S_{W2}.

Next, the height of the upper surface of the embedded insulator 131 is lowered by etching. Consequently, the first side S_{W1} and the second side S_{W2} of the first gate electrode layer 122 are partially exposed. Next, the mask material 201 is peeled off by wet treatment. Consequently, the upper surface S of the first gate electrode layer 122 is completely exposed. Next, a second gate insulator 123 is deposited on the first gate electrode layer 122. Consequently, the second gate insulator 123 that is in contact with the upper surface of the first gate electrode layer 122 (S) and the first and second sides of the first gate electrode layer 122 in the word-line direction (S_{W1} and S_{W2}) is formed. Next, a second gate electrode layer 124 as a polysilicon layer is deposited on the second gate insulator 123 by LPCVD. Consequently, the second gate electrode layer 124 that is in contact with an upper surface of the second gate insulator 123 (σ) and first and second sides of the second gate insulator 123 in the word-line direction (σ_{W1} and σ_{W2}) is formed (FIG. 10G).

In this embodiment, the second gate insulator 123 is a laminated layer as shown in FIG. 3. In this embodiment, the second gate insulator 123 is a laminated layer (ONO) including a first layer 123A as a silicon oxide layer, a second layer 123B as a silicon nitride layer, and a third layer 123C as a silicon oxide layer. The first layer 123A is deposited on the first gate electrode layer 122, the second layer 123B is deposited on the first layer 123A, the third layer 123C is deposited on the second layer 123B, and the second gate electrode layer 124 is deposited on the third layer 123C.

In this embodiment, the second gate insulator 123 is an insulator including three layers. However, the second insulator 123 may be an insulator including one layer, two layers, or four or more layers. In this embodiment, the lowest layer of the second gate insulator 123 (i.e., a layer which is in contact with the first gate insulator 122) is an oxide layer. This is for integrating the lowest layer and the bird's beaks B₁ and B₂, so that the bird's beaks B₁ and B₂ are a part of the second gate insulator 123. In this embodiment, both the first layer 123A and the bird's beaks B₁ and B₂ are silicon oxides. It is desirable that the composition of the lowest layer be identical with the composition of the bird's beaks B₁ and B₂.

The explanation of the manufacturing process is resumed.

Next, a mask material 203 as a silicon nitride layer is deposited on the second gate electrode layer 124 by LPCVD. Next, a photoresist 212 is applied on the mask material 203 (FIG. 10H). As described above, FIG. 10H is a B-B′ sectional view. On the other hand, FIG. 10I shows an A-A′ sectional view at the stage shown in FIG. 10H.

Next, the mask material 203 is processed by lithography. Next, the photoresist 212 is removed. Next, the second gate electrode layer 124, the second gate insulator 123, and the first gate electrode layer 122 are processed by etching (FIG. 10J). In this way, plural trenches T_{W} that penetrate the second gate electrode layer 124, the second gate insulator 123, and the second gate electrode layer 122 and extend in the word-line direction, are formed. Consequently, a first gate electrode 122 and a second gate electrode 124 are formed from the first gate electrode layer 122 and the second gate electrode layer 124, respectively. In FIG. 10J, the upper surface of the first gate electrode 122 (S), first and second sides of the first gate electrode 122 in the bit-line direction (S_{B1} and S_{B2}), and first and second edges of the first gate electrode 122 in the bit-line direction (E_{B1} and E_{B2}) are shown.

Next, sidewall insulators 141 as silicon oxide layers are formed on sidewall surfaces of each of the trenches T_{W} by thermal oxidation. This oxidation process is generally called a post-oxidation process. The oxide layers 141 formed by the oxidation process are generally called post-oxidation layers. Next, ions are implanted in the substrate 111 by ion implantation and activated by thermal annealing. Consequently, source/drain diffusion layers 151 are formed in the substrate 111 (FIG. 10K). In this way, a memory transistor is formed. As described above, FIG. 10K is an A-A′ sectional view. On the other hand, FIG. 10L shows a B-B′ sectional view at the stage shown in FIG. 10K.

As described above, in the first embodiment, the bird's beaks B₁ and B₂ are formed before the second gate insulator 123 is formed. Consequently, in the first embodiment, the edge portions of the second gate insulator 123 in the word-line direction become thicker.

A second embodiment will be explained below. The second embodiment is a modification of the first embodiment. Concerning the second embodiment, differences from the first embodiment are mainly explained. The plan view of FIG. 1A and the circuit configuration of FIG. 1B are common to the first and second embodiments.

### Second Embodiment

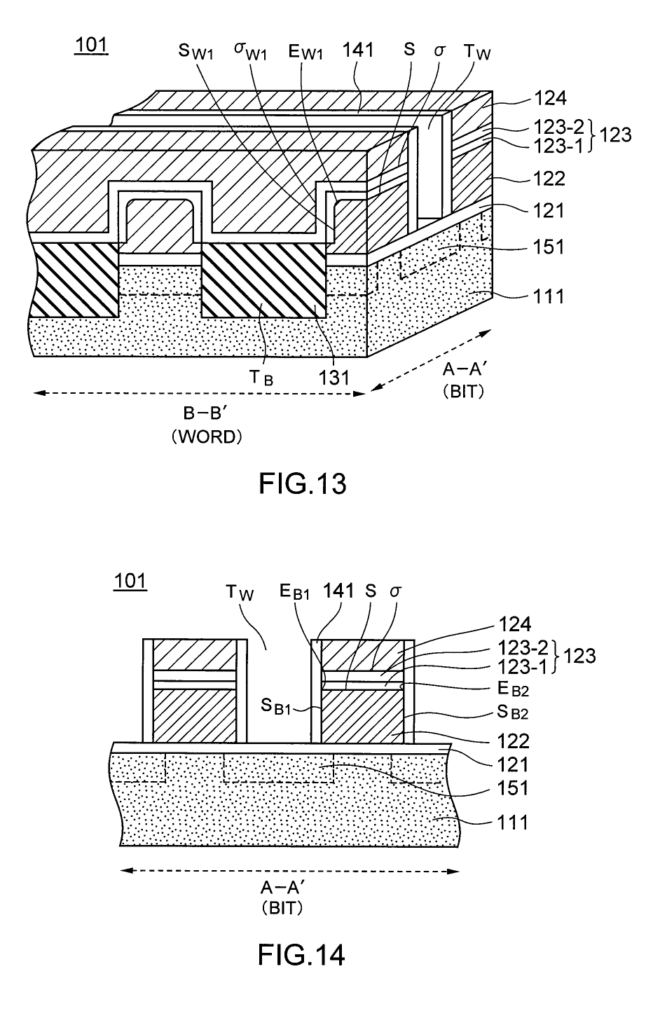

FIG. 11 is a side sectional view of the semiconductor device 101 according to the second embodiment. FIG. 11 is a sectional view on the line B-B′ shown in FIG. 1A, similar to FIG. 2. As shown in FIG. 11, the semiconductor device 101 includes a substrate 111, a first gate insulator 121, a first gate electrode 122, a second gate insulator 123, a second gate electrode 124, and an embedded insulator 131.

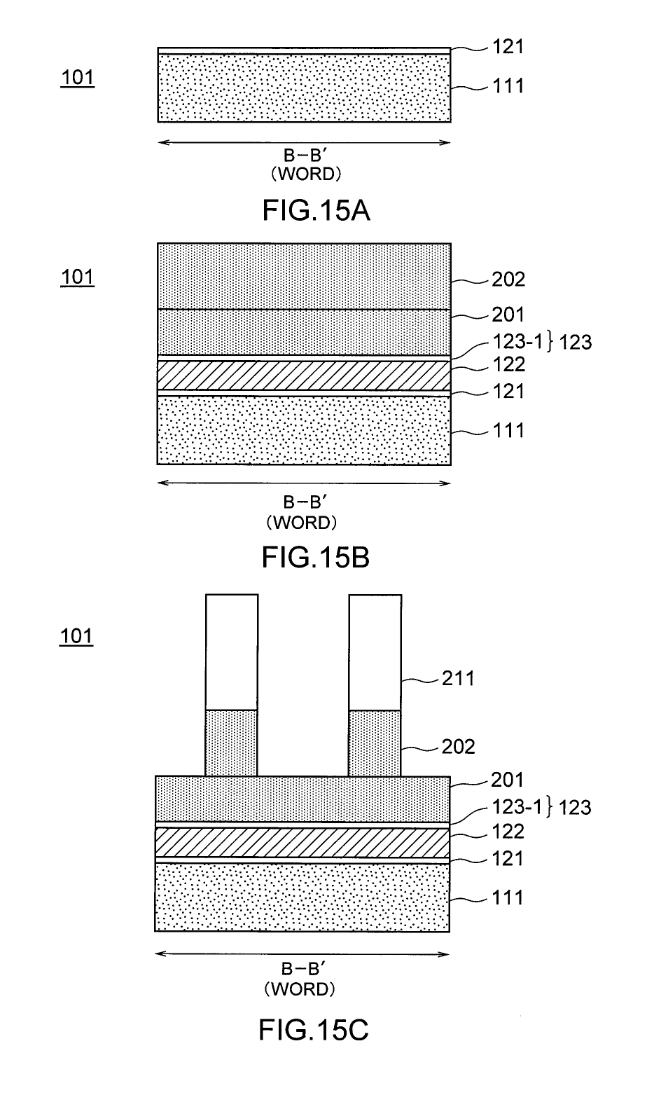

FIG. 12 is an enlarged view of FIG. 11. In this embodiment, the second gate insulator 123 is a laminated layer as shown in FIG. 12. In this embodiment, the second gate insulator 123 is a laminated layer (ONO) including a first layer 123A as a silicon oxide layer, a second layer 123B as a silicon nitride layer, and a third layer 123C as a silicon oxide layer. The first layer 123A is formed on the first gate electrode 122. The second layer 123B is formed on the first layer 123A. The third layer 123C is formed on the second layer 123B. The second gate electrode 124 is formed on the third layer 123C.

FIG. 11 shows a lower layer 123-1 of the second gate insulator 123, and an upper layer 123-2 of the second gate insulator 123. The lower layer 123-1 is a single layer including the first layer 123A. The upper layer 123-2 is a laminated layer including the second layer 123B and the third layer 123C. Details of the lower layer 123-1 and the upper layer 123-2 are described later.

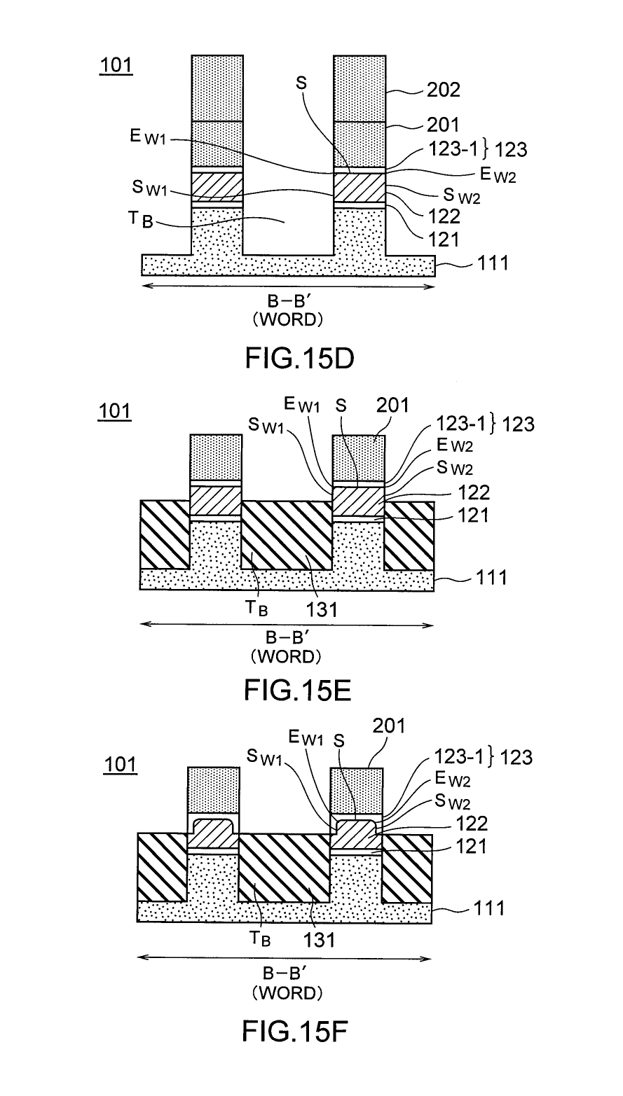

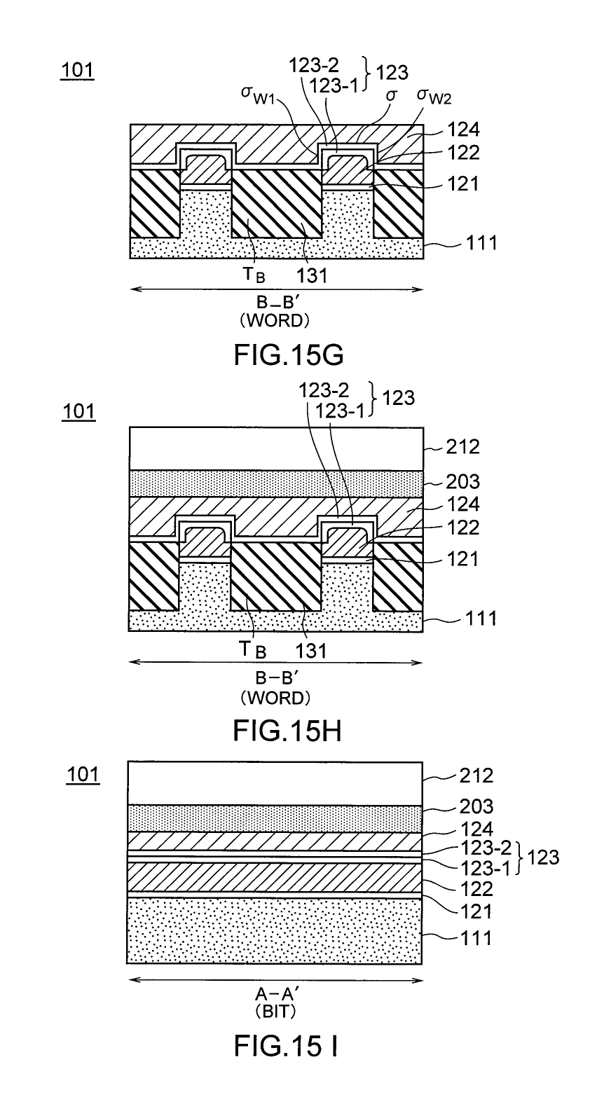

A projected sectional view and a side sectional view of the semiconductor device 101 are shown in FIG. 13 and FIG. 14, respectively. FIG. 13 is a sectional view on the line A-A′ and the line B-B′ shown in FIG. 1A, similar to FIG. 4. FIG. 14 is a sectional view on the line A-A′ shown in FIG. 1A, similar to FIG. 5. As shown in FIGS. 13 and 14, the semiconductor device 101 further includes sidewall insulators 141, and a source/drain diffusion layer 151.

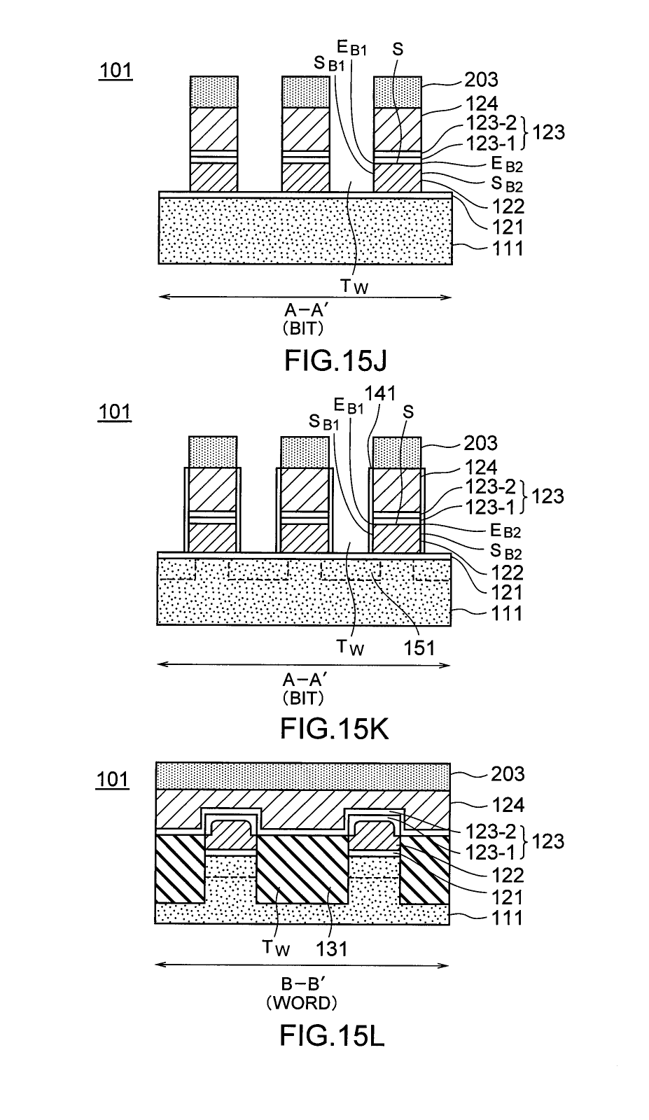

FIGS. 15A to 15L illustrate a manufacturing process of the semiconductor device 101 according to the second embodiment. FIGS. 15A to 15H are sectional views on the line B-B′ shown in FIG. 1A, similar to FIGS. 10A to 10H. FIGS. 15I to 15K are sectional views on the line A-A′ shown in FIG. 1A, similar to FIGS. 10I to 10K. FIG. 15L is a sectional view on the line B-B′ shown in FIG. 1A, similar to FIG. 10L.

First, a first gate insulator 121 as a silicon oxide layer is deposited on a silicon substrate 111 by thermal oxidation (FIG. 15A).

Next, a first gate electrode layer 122 as a polysilicon layer is deposited on the first gate insulator 121 by CVD. Next, a lower layer 123-1 of a second gate insulator 123 is deposited on the first gate electrode layer 122 by CVD. Next, a mask material 201 as a silicon nitride layer is deposited on the lower layer 123-1 of the second gate insulator 123. Next, a mask material 202 as an oxide layer is deposited on the mask material 201 (FIG. 15B).

Next, a photoresist 211 is applied on the mask material 202. Next, the mask material 202 is processed by lithography (FIG. 15C).

Next, the photoresist 211 is removed. Next, the mask material 201, the lower layer 123-1, the first gate electrode layer 122, the first gate insulator 121, and the substrate 111 are processed (FIG. 15D). In this way, plural trenches T_{B} that penetrate the lower layer 123-1, the first gate electrode layer 122, and the first gate insulator 121 and extend in the bit-line direction, are formed. Consequently, the lower layer 123-1, the first gate electrode layer 122, and the first gate insulator 121 having a strip shape and whose first and second sides in the word-line direction are exposed, are formed. In FIG. 15D, an upper surface of the first gate electrode layer 122 (S), first and second sides of the first gate electrode layer 122 in the word-line direction (S_{W1} and S_{W2}), and first and second edges of the first gate electrode layer 122 in the word-line direction (E_{W1} and E_{W2}) are shown.

Next, an embedded insulator 131 is deposited in each of the trenches T_{B}. Next, the embedded insulator 131 is polished and planarized by CMP until an upper surface of the mask material 201 is exposed. Consequently, the embedded insulator 131 and the mask material 202 up to the upper surface of the mask material 201 are removed. Next, the height of the upper surface of the embedded insulator 131 is lowered by etching. Consequently, the height of the upper surface of the embedded insulator 131 is lowered to a height between the upper surface of the first gate electrode layer 122 (S) and the lower surface of the first gate electrode layer 122. In other words, a part of the first gate electrode layer 122 is embedded in the insulator 131 (FIG. 15E).

Next, an oxidation process is applied to a wafer surface to oxidize exposed surfaces of the first side S_{W1} and the second side S_{W2} including the first edge E_{W1} and the second edge E_{W2} (FIG. 15F). In other words, the exposed surfaces of the first side S_{W1} and the second side S_{W2} including the first edge E_{W1} and the second edge E_{W2} are altered into insulators. In this embodiment, the insulators are oxides, more specifically, silicon oxides.

Next, the mask material 201 is peeled off by wet treatment. Consequently, an upper surface of the lower layer 123-1 of the second gate insulator 123 is exposed. Next, an upper layer 123-2 of the second gate insulator 123 is deposited on the lower layer 123-1 of the second gate electrode layer 122. Consequently, the upper layer 123-2 that is in contact with the upper surface of the lower layer 123-1 and first and second sides of the lower layer 123-1 in the word-line direction is formed. Next, a second gate electrode layer 124 as a polysilicon layer is deposited on (the upper layer 123-2 of) the second gate insulator 123 by LPCVD. Consequently, the second gate electrode layer 124 that is in contact with an upper surface of the second gate insulator 123 (σ) and first and second sides of the second gate insulator 123 in the word-line direction (σ_{W1} and σ_{W2}) is formed (FIG. 15G).

In this embodiment, the second gate insulator 123 is a laminated layer as shown in FIG. 12. In this embodiment, the second gate insulator 123 is a laminated layer (ONO) including a first layer 123A as a silicon oxide layer, a second layer 123B as a silicon nitride layer, and a third layer 123C as a silicon oxide layer. The first layer 123A is deposited on the first gate electrode layer 122, the second layer 123B is deposited on the first layer 123A, the third layer 123C is deposited on the second layer 123B, and the second gate electrode layer 124 is deposited on the third layer 123C.

In this embodiment, the second gate insulator 123 is an insulator including three layers. However, the second insulator 123 may be an insulator including one layer, two layers, or four or more layers. In this embodiment, the lower layer 123-1 is an insulator including one layer. However, the lower layer 123-1 may be an insulator including two or more layers. In this embodiment, the upper layer 123-2 is an insulator including two layers. However, the upper layer 123-2 may be an insulator including one layer or three or more layers. In this embodiment, the lowest layer of the second gate insulator 123 (i.e., a layer that is in contact with the first gate insulator 122) is an oxide layer. This is for integrating the lowest layer and the oxide layer formed by the oxidation process shown in FIG. 15F, so that the oxide layer is a part of the second gate insulator 123. In this embodiment, both the first layer 123A and the oxide layer are silicon oxide layers. It is desirable that the composition of the lowest layer be identical with the composition of the oxide layer.

The explanation of the manufacturing process is resumed.

Next, a mask material 203 as a silicon nitride layer is deposited on the second gate electrode layer 124 by LPCVD. Next, a photoresist 212 is applied on the mask material 203 (FIG. 15H). As described above, FIG. 15H is a B-B′ sectional view. On the other hand, FIG. 15I shows an A-A′ sectional view at the stage shown in FIG. 15H.

Next, the mask material 203 is processed by lithography. Next, the photoresist 212 is removed. Next, the second gate electrode layer 124, the second gate insulator 123, and the first gate electrode layer 122 are processed by etching (FIG. 15J). In this way, plural trenches T_{W} that penetrate the second gate electrode layer 124, the second gate insulator 123, and the second gate electrode layer 122 and extend in the word-line direction, are formed. Consequently, a first gate electrode 122 and a second gate electrode 124 are formed from the first gate electrode layer 122 and the second gate electrode layer 124, respectively. In FIG. 15J, the upper surface of the first gate electrode 122 (S), first and second sides of the first gate electrode 122 in the bit-line direction (S_{B1} and S_{B2}), and first and second edges of the first gate electrode 122 in the bit-line direction (E_{B1} and E_{B2}) are shown.

Next, sidewall insulators 141 as silicon oxide layers are formed on sidewall surfaces of each of the trenches T_{W} by thermal oxidation. This oxidation process is generally called a post-oxidation process. The oxide layers 141 formed by the oxidation process are generally called post-oxidation layers. Next, ions are implanted in the substrate 111 by ion implantation and activated by thermal annealing. Consequently, source/drain diffusion layers 151 are formed in the substrate 111 (FIG. 15K). In this way, a memory transistor is formed. As described above, FIG. 15K is an A-A′ sectional view. On the other hand, FIG. 15L shows a B-B′ sectional view at the stage shown in FIG. 15K.

As described above, in the second embodiment, by oxidizing edge of the first gate electrode layer 122 in the word-line direction, edge portions of the second gate insulator 123 in the word-line direction become thicker.

As described above, according to the embodiments of the present invention, concerning a semiconductor device including first and second gate insulators and first and second gate electrodes, it is possible to reduce a leak current between the first gate electrode and the second gate electrode.

1. A semiconductor device including a bit line and a word line, the semiconductor device comprising:
a first gate insulator formed on a substrate;
a first gate electrode formed on the first gate insulator;
a second gate insulator formed on the first gate electrode,
the second gate insulator being in contact with
an upper surface of the first gate electrode,
a first side of the first gate electrode in a word-line direction, and
a second side of the first gate electrode in the word-line direction; and
regarding the thickness of the second gate insulator,
the thickness of the insulator, on a first edge of the first gate electrode in the word-line direction, and
the thickness of the insulator, on a second edge of the first gate electrode in the word-line direction
being larger than each of
the thickness of the insulator, on the upper surface of the first gate electrode,
the thickness of the insulator, on the first side of the first gate electrode in the word-line direction, and
the thickness of the insulator, on the second side of the first gate electrode in the word-line direction; and
a second gate electrode formed on the second gate insulator,
the second gate electrode being in contact with
an upper surface of the second gate insulator,
a first side of the second gate insulator in the word-line direction, and
a second side of the second gate insulator in the word-line direction.

2. The semiconductor device according to claim 1, wherein,
regarding the thickness of the second gate insulator,
the thickness of the insulator, on the first edge of the first gate electrode in the word-line direction, and
the thickness of the insulator, on the second edge of the first gate electrode in the word-line direction
are larger than each of
the thickness of the insulator, on a first edge of the first gate electrode in a bit-line direction, and
the thickness of the insulator, on a second edge of the first gate electrode in the bit-line direction.

3. The semiconductor device according to claim 1, wherein,
regarding the thickness of the second gate insulator,
the thickness of the insulator, on the first side of the first gate electrode in the word-line direction, and
the thickness of the insulator, on the second side of the first gate electrode in the word-line direction
are equal to
the thickness of the insulator, on the upper surface of the first gate electrode.

4. The semiconductor device according to claim 2, wherein,
regarding the thickness of the second gate insulator,
the thickness of the insulator, on the first edge of the first gate electrode in the bit-line direction, and
the thickness of the insulator, on the second edge of the first gate electrode in the bit-line direction
are equal to
the thickness of the insulator, on the upper surface of the first gate electrode.

5. The semiconductor device according to claim 1, wherein,
regarding the capacity thickness of the second gate insulator,
the capacity thickness of the insulator, on the first edge of the first gate electrode in the word-line direction, and
the capacity thickness of the insulator, on the second edge of the first gate electrode in the word-line direction
are 1.8 time or more as large as
the capacity thickness of the insulator, on the upper surface of the first gate electrode.

6. The semiconductor device according to claim 1, wherein the second gate insulator include one or more layers of insulators.

7. The semiconductor device according to claim 6, wherein the lowest layer of the second gate insulator is an oxide layer.

8. The semiconductor device according to claim 6, wherein the second gate insulator includes a first oxide layer, a nitride layer formed on the first oxide layer, and a second oxide layer formed on the nitride layer.

9. A method of manufacturing a semiconductor device including a bit line and a word line, the method comprising:
depositing a first gate insulator on a substrate;
depositing a first gate electrode layer on the first gate insulator;
forming plural trenches which penetrate the first gate electrode layer and the first gate insulator and extend in a bit-line direction, to form the first gate electrode layer and the first gate insulator having a strip shape and whose first and second sides in a word-line direction are exposed;
embedding, in the plural trenches, an insulator in which the first gate insulator and a part or all of the first gate electrode layer are embedded;
altering first and second edges of the first gate electrode layer in the word-line direction, into insulators;
depositing a second gate insulator that is in contact with an upper surface of the first gate electrode layer, and first and second sides of the first gate electrode layer in the word-line direction;
depositing a second gate electrode layer that is in contact with an upper surface of the second gate insulator, and first and second sides of the second gate insulator in the word-line direction; and
forming plural trenches which penetrate the second gate electrode layer, the second gate insulator, and the first gate electrode layer and extend in the word-line direction, to form a first gate electrode and a second gate electrode.

10. A method of manufacturing a semiconductor device including a bit line and a word line, the method comprising:
depositing a first gate insulator on a substrate;
depositing a first gate electrode layer on the first gate insulator;
depositing a lower layer of a second gate insulator on the first gate electrode layer;
forming plural trenches which penetrate the lower layer of the second gate insulator, the first gate electrode layer, and the first gate insulator and extend in a bit-line direction, to form the lower layer of the second gate insulator, the first gate electrode layer, and the first gate insulator having a strip shape and whose first and second sides in a word-line direction are exposed;
embedding, in the plural trenches, an insulator in which the first gate insulator and a part or all of the first gate electrode layer are embedded;
altering first and second edges of the first gate electrode layer in the word-line direction, into insulators;
depositing an upper layer of the second gate insulator that is in contact with an upper surface of the lower layer of the second gate insulator, and first and second sides of the lower layer of the second gate insulator in the word-line direction;
depositing a second gate electrode layer that is in contact with an upper surface of the upper layer of the second gate insulator, and first and second sides of the upper layer of the second gate insulator in the word-line direction; and
forming plural trenches which penetrate the second gate electrode layer, the second gate insulator, and the first gate electrode layer and extend in the word-line direction, to form a first gate electrode and a second gate electrode.

11. The method according to claim 9, wherein,
regarding the capacity thickness of the second gate insulator,
the capacity thickness of the insulator, on the first edge of the first gate electrode in the word-line direction, and
the capacity thickness of the insulator, on the second edge of the first gate electrode in the word-line direction
are 1.8 time or more as large as
the capacity thickness of the insulator, on the upper surface of the first gate electrode.

12. The method according to claim 9, wherein, when the altering is performed, the height of an upper surface of the embedded insulator is set to a height that makes it possible to alter the first and second edges of the first gate electrode layer in the word-line direction, into insulators.

13. The method according to claim 9, wherein, when the altering is performed, the height of an upper surface of the embedded insulator is set higher than the height of a lower surface of the first gate electrode layer.

14. The method according to claim 9, wherein, when the altering is performed, the upper surface of the first gate electrode layer is covered with a mask material.

15. The method according to claim 9, wherein the insulators formed by the altering are oxides.

16. The method according to claim 9, wherein, in the altering, bird's beaks are inserted in the first and second edges of the first gate electrode layer in the word-line direction, to alter the first and second edges of the first gate electrode layer in the word-line direction, into insulators.

17. The method according to claim 9, wherein the second gate insulator includes one or more layers of insulators.

18. The method according to claim 17, wherein the lowest layer of the second gate insulator is an oxide layer.

19. The method according to claim 17, wherein the composition of the lowest layer of the second gate insulator is identical with the composition of the insulators formed by the altering.
